(19) United States
(12) Patent Application Publication
(10) Pub. No.: US 2025/0131157 A1
(43) Pub. Date: Apr. 24, 2025

(54) ARTIFICIAL INTELLIGENCE (AI) MODEL CREATION METHOD AND EXECUTION METHOD

(71) Applicant: SigmaStar Technology Ltd., Xiamen (CN)

(72) Inventor: Xiao Long Liu, Shanghai (CN)

(21) Appl. No.: 18/818,685

(22) Filed: Aug. 29, 2024

(30) Foreign Application Priority Data
Oct. 19, 2023 (CN) 202311360439.0

(51) Int. Cl. G06F 30/20

(52) U.S. Cl. CPC G06F 30/20

(57) ABSTRACT

A method for creating an artificial intelligence (AI) model is applied to an intelligence processing unit (IPU). The IPU includes a computing circuit and a memory. The AI model includes a plurality of operators. The computing circuit generates an intermediate tensor in the process of executing each operator. The method includes the following steps: (A) dividing the operators according to a batch threshold, life cycles of the intermediate tensors, sizes of the intermediate tensors, and a capacity of the memory; (B) calculating a bandwidth requirement of the IPU for an external memory when executing the AI model; and (C) storing a relationship between the batch threshold and the bandwidth requirement. The AI model performs an operation of the same operator on N batches of input data substantially at the same time, and N is a positive integer.

This application claims the benefit of China application Serial No. 202311360439.0, filed on Oct. 19, 2023, the subject matter of which is incorporated herein by reference.

### BACKGROUND OF THE INVENTION

### 1. Field of the Invention

The present invention generally relates to artificial intelligence (AI), and, more particularly, to a method for creating an AI model and a method for executing the same.

### 2. Description of Related Art

FIG. 1 shows a conventional artificial intelligence (AI) model. The AI model 100 includes operators OP0, OP1, OP2, and OP3. When multiple batches of input data (or referred to as input feature maps or tensors) are inputted into the AI model 100, the input data of the current batch (e.g., the input data BT0) undergoes the operations of the operators OP0 through OP3 in sequence before the input data of the next batch (e.g., the input data BT1) undergoes the operations of the operators OP0 through OP3 in sequence. The same procedure is followed to continue to complete the operations of the operators OP0 through OP3 on the input data BT2 and BT3.

The AI model 100 is executed by a processing unit, which usually contains an internal memory (e.g., a Static Random Access Memory (SRAM)). The disadvantage of the AI model 100 is that because the processing unit processes only one batch of input data at a time, it cannot make full use of the internal memory, resulting in a waste of hardware resources. In addition, when the internal memory cannot be fully utilized, the processing unit needs to frequently read data from an external memory (e.g., a Dynamic Random Access Memory, DRAM), resulting in an increased bandwidth requirement, which in turn leads to reduced performance of the circuit system.

### SUMMARY OF THE INVENTION

In view of the issues of the prior art, an object of the present invention is to provide a method for creating an artificial intelligence (AI) model and a method for executing an AI model, so as to make an improvement to the prior art.

According to one aspect of the present invention, a method for creating an AI model is provided. The method is applied to an intelligence processing unit (IPU) including a computing circuit and a memory. The AI model includes a plurality of operators, and the computing circuit generates an intermediate tensor in a process of executing each operator. The method includes the following steps: (A) dividing the plurality of operators according to a batch threshold, life cycles of the intermediate tensors, sizes of the intermediate tensors, and a capacity of the memory; (B) calculating a bandwidth requirement of the IPU for an external memory when executing the AI model; and (C) storing a relationship between the batch threshold and the bandwidth requirement. The AI model performs an operation of a same operator on N batches of input data substantially simultaneously, N being a positive integer.

According to another aspect of the present invention, a method for executing an AI model is provided. The method is applied to an electronic device including an IPU and a memory. The IPU does not include the memory. The AI model performs an operation of a same operator on M batches of input data substantially simultaneously, and M is a positive integer. The method includes the following steps: (A) splitting a to-be-processed batch number into a plurality of sub-batch numbers according to a plurality of batch thresholds and a plurality of bandwidth requirements of the IPU for the memory, wherein the plurality of batch thresholds and the plurality of bandwidth requirements correspond to each other; and (B) executing the AI model using one of the plurality of sub-batch numbers as the M.

The technical means embodied in the embodiments of the present invention can solve at least one of the problems of the prior art. Therefore, compared to the prior art, the present invention can make full use of hardware resources and reduce bandwidth.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows a conventional artificial intelligence (AI) model.

FIG. 2 is a functional block diagram of an electronic device according to an embodiment of the present invention.

FIG. 3 shows a schematic diagram of an AI model according to an embodiment of the present invention.

FIG. 4 is a flowchart of a method for creating an AI model according to an embodiment of the present invention.

FIG. 5 illustrates the relationship between a bandwidth requirement and a batch threshold N according to an embodiment of the present invention.

FIG. 6 is the flowchart of step S420 in FIG. 4 according to an embodiment.

FIGS. 7A through 7B are the schematic diagrams of the process of dividing an AI model.

FIG. 8 shows a schematic diagram of an AI model according to another embodiment of the present invention.

FIG. 9A is the flowchart of step S420 in FIG. 4 according to another embodiment.

FIG. 9B shows a schematic diagram of an AI model according to another embodiment of the present invention.

FIG. 10 is a functional block diagram of an electronic device according to an embodiment of the present invention.

FIGS. 11A through 11B are the flowcharts of step S420 in FIG. 4 according to another embodiment.

FIGS. 12A through 12B are the schematic diagrams of the process of dividing an AI model.

FIG. 13 is a flowchart of a method for executing AI according to an embodiment of the present invention.

FIG. 14 is the flowchart of step S1310 in FIG. 13 according to an embodiment.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes a method for creating an artificial intelligence (AI) model and a method for executing an AI model. On account of that some or all elements of the intelligence processing unit (IPU) could be known, the detail of such elements is omitted provided that such detail has little to do with the features of this disclosure, and that this omission nowhere dissatisfies the specification and enablement requirements. Some or all of the processes of the method for creating an AI model and the method for executing an AI model may be implemented by software and/or firmware. A person having ordinary skill in the art can choose components or steps equivalent to those described in this specification to carry out the present invention, which means that the scope of this invention is not limited to the embodiments in the specification.

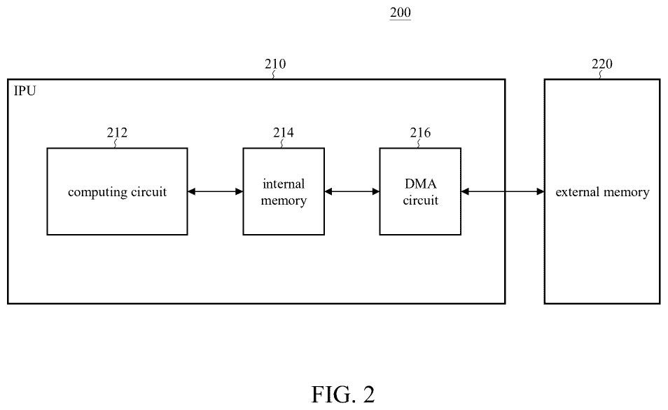

Reference is made to FIG. 2, which is a functional block diagram of an electronic device according to an embodiment of the present invention. The electronic device 200 includes an IPU 210 and an external memory 220. The IPU 210 and the external memory 220 are coupled to each other. The IPU 210 includes a computing circuit 212, an internal memory 214, and a direct memory access (DMA) circuit 216 but does not include the external memory 220. The computing circuit 212, the internal memory 214, and the DMA circuit 216 are coupled to each other. The DMA circuit 216 is coupled to the external memory 220. The IPU 210 reads data from the external memory 220 or writes data into the external memory 220 through the DMA circuit 216.

In some embodiments, the external memory 220 can be a DRAM, while the internal memory 214 can be an SRAM.

The external memory 220 stores the input data and weights (or referred to as convolution kernels) of an AI model. The internal memory 214 stores multiple tensors or multiple tiles (a tile is a portion of a tensor) of the input data and at least one subset of the weights. The computing circuit 212 may include multiple engines (including, but not limited to, vector engines and convolution engines), which read the tensors (or tiles) and/or weights from the internal memory 214, process the tensors or the tiles (e.g., performing vector operations or convolution operations), and then store the processed results (e.g., the output feature map) in the internal memory 214.

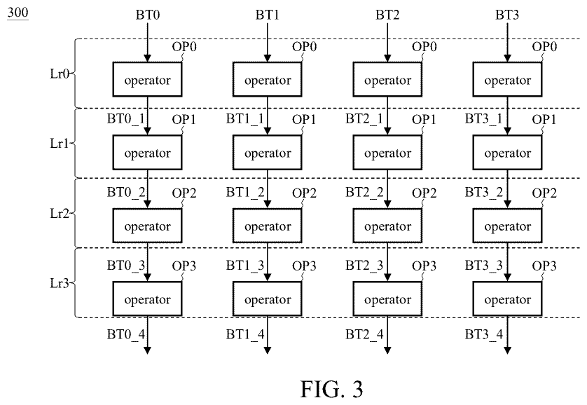

FIG. 3 shows a schematic diagram of an AI model according to an embodiment of the present invention. The AI model 300 contains multiple layers of operations (the example in FIG. 3 contains four operation layers: Lr0 to Lr3), and each layer of operations processes the input data BT0 through BT3 or the data derived from it (intermediate tensors).

Continuing the previous paragraph, the computing circuit 212 of the present invention sequentially processes the operations of the operation layers Lr0, Lr1, Lr2, and Lr3. More specifically, the operation of the operation layer Lr0 includes the operation of the operator OP0 on the input data BT0, BT1, BT2, and BT3. Similarly, the operation of the operation layer Lr1 (Lr2 or Lr3) includes the operation of the operator OP1 (OP2 or OP3) on the intermediate tensor derived from the input data BT0 through BT3 (more specifically, the output of its corresponding operators OP0 through OP2).

For the input data BT0, the intermediate tensor BT0_1 is the output of the operator OP0 and the input of the operator OP1. The intermediate tensor BT0_2 is the output of the operator OP1 and the input of the operator OP2. The intermediate tensor BT0_3 is the output of the operator OP2 and the input of the operator OP3. The intermediate tensor BT0_4 is the output of the operator OP3.

Similarly, for the input data BT1 (BT2 or BT3), the intermediate tensor BT1_1 (BT2_1 or BT3_1) is the output of the operator OP0 and the input of the operator OP1. The intermediate tensor BT1_2 (BT2_2 or BT3_2) is the output of the operator OP1 and the input of the operator OP2. The intermediate tensor BT1_3 (BT2_3 or BT3_3) is the output of the operator OP2 and the input of the operator OP3. The intermediate tensor BT1_4 (BT2_4 or BT3_4) is the output of the operator OP3.

In some embodiments, the computing circuit 212 may include K cores (K is greater than or equal to 1). In the operation of a certain operation layer, the K core(s) cycle(s) to process all of the input data (i.e., the input data BT0 through BT3 in the example of FIG. 3) or the intermediate tensors BTx_y (0<=x<=3 and 1<=y<=3).

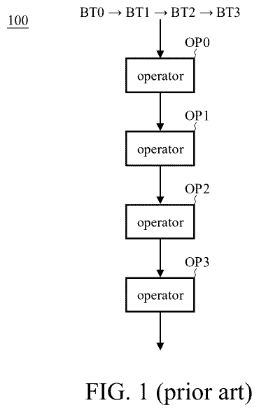

In comparison with the AI model 100 in FIG. 1, since the AI model 300 in FIG. 3 processes multiple batches of input data at substantially the same time, the internal memory 214 stores more tensors or tiles at the same time, meaning that the internal memory 214 is more fully utilized. The advantage of such a design is that the bandwidth requirement of the IPU 210 for the external memory 220 can be reduced. This is because when the IPU 210 (more specifically, the computing circuit 212) processes the operation layer Lr0 (Lr1, Lr2, or Lr3), it only needs to read the corresponding weight from the external memory 220 once (because the same operation layer processes the same operator). For comparison purposes, although the AI model 100 performs 4 operations for each operator (OP0, OP1, OP2, or OP3) (assuming there are 4 batches of input data), the AI model 100 does not perform the operation of the same operator on the 4 batches of input data at substantially the same time. This causes the AI model 100 to have to frequently read the corresponding weights from the external memory, increasing the requirement for bandwidth.

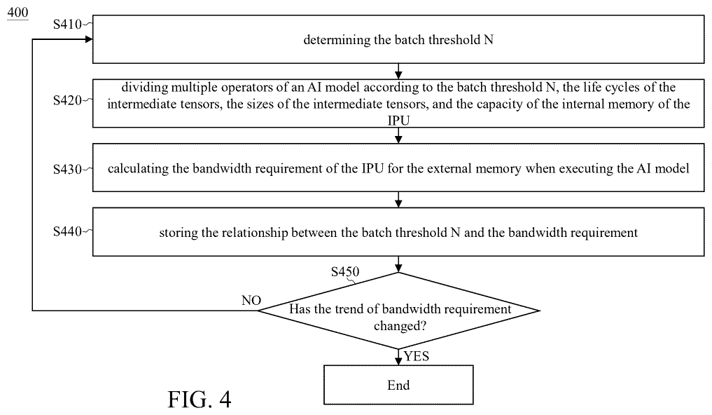

Based on the aforementioned operating principle, the present invention provides a method for creating an AI model. Reference is made to FIG. 4, which is a flowchart of a method for creating an AI model according to an embodiment of the present invention. The method 400 for creating an AI model includes the following steps.

Step S410: Determining the batch threshold N. When the step S410 is executed for the first time, the batch threshold Nis set to a default value (e.g., 1). When the step S410 is executed again, the batch threshold N is changed according to a preset rule.

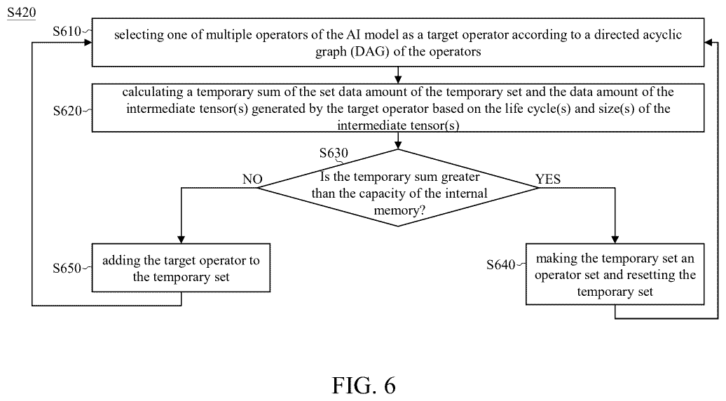

Step S420: Dividing multiple operators of an AI model according to the batch threshold N, the life cycles of the intermediate tensors, the sizes of the intermediate tensors, and the capacity of the internal memory 214 of the IPU 210. Step S420 will be discussed in detail below with reference to FIG. 6.

Step S430: Calculating the bandwidth requirement of the IPU 210 for the external memory 220 when executing the AI model. The bandwidth requirement corresponds to the current batch threshold N and the division result of step S420. The lower (higher) the bandwidth requirement, the higher (lower) the performance of the IPU 210 when executing the AI model.

Step S440: Storing the relationship between the batch threshold N and the corresponding bandwidth requirement.

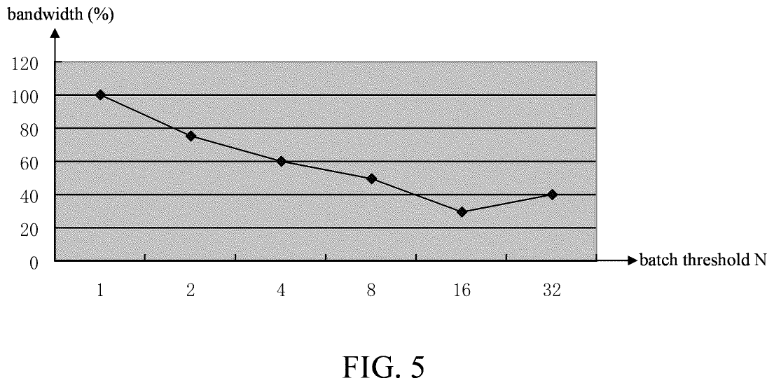

Step S450: Determining whether the trend of bandwidth requirement has changed. Reference is made to FIG. 5, which illustrates the relationship between bandwidth requirement and the batch threshold N according to an embodiment of the present invention. When the batch threshold N is 1, 2, 4, 8, 16, 32, the bandwidth usage is approximately 100%, 75%, 60%, 50%, 30%, and 40% respectively; that is, step S440 stores the relationship between 1, 2, 4, 8, 16, 32 and 100%, 75%, 60%, 50%, 30%, 40%. When the batch threshold N is less than or equal to 16, there is a downward trend in bandwidth usage (indicating that the internal memory 214 is not fully utilized), and when the batch threshold N equals 32, the trend in bandwidth requirement changes (indicating that the internal memory 214 has reached its maximum utilization rate before the batch threshold 32). In other words, in the example of FIG. 5, when the batch threshold N equals 16, the bandwidth requirement of the IPU 210 for the external memory 220 is relatively low (i.e., the utilization rate of the internal memory 214 by the IPU 210 is relatively high). When the result of step S450 is YES, the method 400 for creating an AI model ends. When the result of step S450 is NO, the process returns to step S410 to determine the next batch threshold N.

In the example of FIG. 5, the batch threshold N is increased based on a geometric progression (e.g., powers of 2). In other embodiments, the batch threshold N can be changed based on other rules (e.g., an arithmetic progression).

In some embodiments, the method 400 for creating an AI model is performed by a development device (e.g., a general-purpose computer) during the development phase of the electronic device 200 (more specifically, the IPU 210).

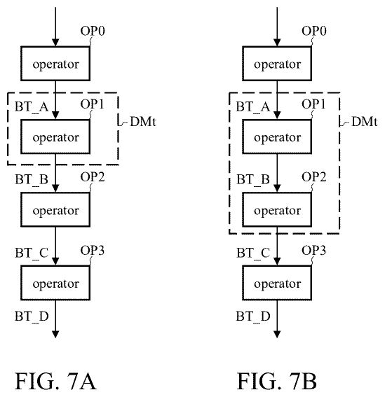

Reference is made to FIG. 6, which is a flowchart of step S420 in FIG. 4 according to an embodiment of the present invention. Step S420 includes the following sub-steps. Reference is made to both FIGS. 7A and 7B for the following discussion. FIGS. 7A and 7B are the schematic diagrams of the process of dividing the AI model. It should be noted that FIGS. 7A and 7B are the simplified schematic diagrams. The actual operational details are as shown in FIG. 3 (i.e., multiple input data are processed simultaneously), not as shown in FIG. 1 (i.e., multiple input data are processed sequentially).

Step S610: Selecting one of multiple operators of the AI model as a target operator according to the directed acyclic graph (DAG) of the operators. Referring to FIG. 7A, if the current temporary set DMt contains only the operator OP1, then step S610 selects the operator next to the temporary set DMt (i.e., the operator OP2) as the target operator.

Step S620: Calculating the temporary sum of the set data amount of the temporary set and the data amount of the intermediate tensor(s) generated by the target operator based on the life cycle(s) and size(s) of the intermediate tensor(s). As shown in FIG. 7A, when the computing circuit 212 executes the operator OP2, the intermediate tensor BT_A (which is the output of the operator OP0 as well as the input of the operator OP1 or the temporary set DMt) is non-alive (i.e., which means it does not occupy the internal memory 214), while the intermediate tensor BT_B (which is the output of the operator OP1 or the temporary set DMt as well as the input of the operator OP2) and the intermediate tensor BT_C (which is the output of the operator OP2 as well as the input of the operator OP3) are alive (i.e., which means they occupy the internal memory 214). As a result, the temporary sum is equal to the sum of the data amount of the intermediate tensor BT_B and the data amount of the intermediate tensor BT_C. Therefore, the temporary sum is associated with the peak of the intermediate tensors, which refers to the total data amount of the maximum number of simultaneously alive intermediate tensors.

Step S630: Determining whether the temporary sum is greater than the capacity of the internal memory 214. If YES (indicating that the target operator cannot be added to the current temporary set DMt), then the flow proceeds to step S640; if NO (indicating that the target operator can be added to the current temporary set DMt), then the flow proceeds to step S650.

Step S640: Making the temporary set an operator set, resetting the temporary set (i.e., setting the number of operators in the temporary set to 0), and then returning to step S610.

Step S650: Adding the target operator to the temporary set DMt (as shown in FIG. 7B), and then returning to step S610 (in the example of FIG. 7B, the target operator is the operator OP3).

It should be noted that the intermediate tensors BT_A to BT D are associated with the number of batches (M) that the IPU 210 processes at the same time. Reference is made to FIG. 3. For example, when the number of batches (M) is 2, the intermediate tensor BT_A contains the intermediate tensors BT0_1 and BT1_1, the intermediate tensor BT_B contains the intermediate tensors BT0_2 and BT1_2, and so on. When the number of batches (M) is 4, the intermediate tensor BT_A contains the intermediate tensors BT0_1, BT1_1, BT2_1, and BT3_1, the intermediate tensor BT_B contains the intermediate tensors BT0_2, BT1_2, BT2_2, and BT3_2, and so on.

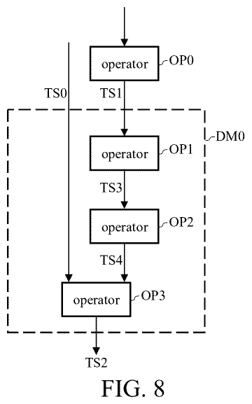

FIG. 8 shows a schematic diagram of an AI model according to another embodiment of the present invention. In the example of FIG. 8, the operators OP1, OP2, and OP3 are grouped into the same operator set DM0.

When the computing circuit 212 executes the operator set DM0, the data inputted into the operator set DM0 (i.e., the intermediate tensors TS0 and TS1) and the data outputted from the operator set DM0 (i.e., the intermediate tensor TS2) must be changed according to the batch number. More specifically, the internal memory 214 may include a plurality of tensor buffers, and a tensor buffer stores data corresponding to a batch number. For example, when the input data is switched from the input data BT0 to the input data BT1, the computing circuit 212 must obtain the intermediate tensors TS0 and TS1 from the tensor buffer of the internal memory 214 corresponding to the input data BT1 and store the intermediate tensor TS2 in the corresponding tensor buffer.

The intermediate tensor TS3 and the intermediate tensor TS4 are the temporary data generated when the computing circuit 212 processes the operator set DM0. These temporary data do not need to be retained for a long time, and there is no need to switch the corresponding tensor buffer.

In summary, the method for creating an AI model of the present invention can enable the IPU 210 to effectively utilize the internal memory 214 and reduce the bandwidth requirement for the external memory 220 when executing the AI model.

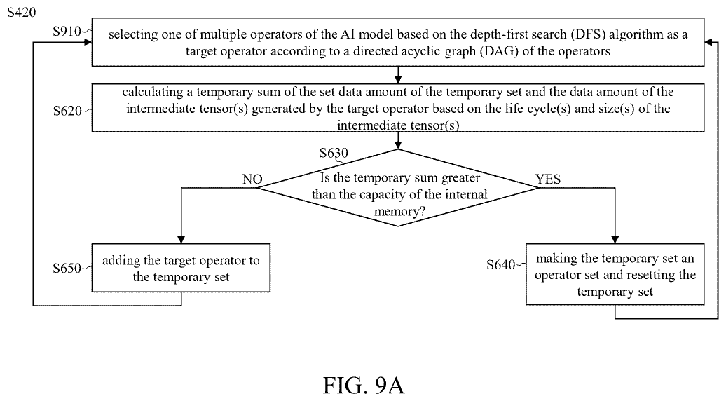

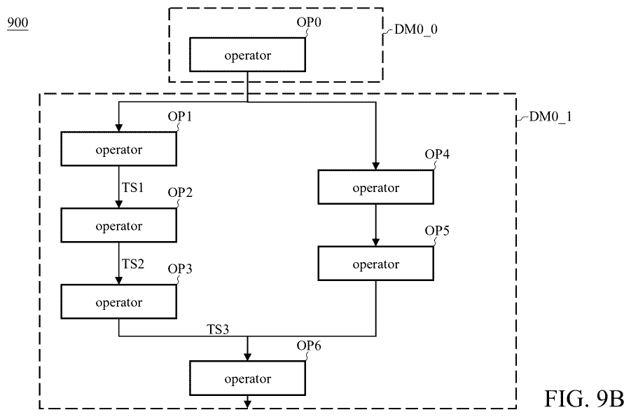

Reference is made to FIG. 9A, which shows a flowchart of step S420 in FIG. 4 according to another embodiment of the present invention. The following discussion, in conjunction with FIG. 9B, will illustrate how to further enhance the utilization rate of the internal memory 214. FIG. 9B shows a schematic diagram of the AI model according to another embodiment of the present invention. The AI model 900 contains the operators OP0 to OP6. The operator OP0 belongs to the operator set DM0_0, while the operators OP1 to OP6 belong to another operator set DM0_1. In this embodiment, when the development device executes step S910 in FIG. 9A, it selects one of the operators as the target operator based on the depth-first search (DFS) algorithm. Steps S620 to S650 in FIG. 9A are the same as steps S620 to S650 in FIG. 6.

The advantage of determining the target operator based on the DFS algorithm is that the life cycle(s) of the intermediate tensor(s) can be shortened, thereby reducing the time the intermediate tensor(s) occupies (or occupy) the internal memory 214. For example, in FIG. 9B, according to the DFS algorithm, the operators OP1 to OP5 are selected in the following order: OP1→OP2→OP3→OP4→OP5; in this case, the life cycle of the intermediate tensor TS1 ends in the third step (when the operator OP3 is selected) (i.e., the intermediate tensor TS1 no longer occupies memory at this time). In comparison, according to the breadth-first search algorithm (BFS), the operators OP1 to OP5 are selected in the following order: OP1→OP4→OP2→OP5→OP3; in this case, the life cycle of the intermediate tensor TS1 ends in the fifth step (when the operator OP3 is selected).

The shorter the life cycle of the intermediate tensor, the less time it occupies the internal memory 214. Consequently, the internal memory 214 can be utilized more effectively, allowing the IPU 210 to decrease the frequency of accessing the external memory 220 (i.e., reducing the bandwidth requirement). This contributes to enhancing the overall performance of the electronic device 200.

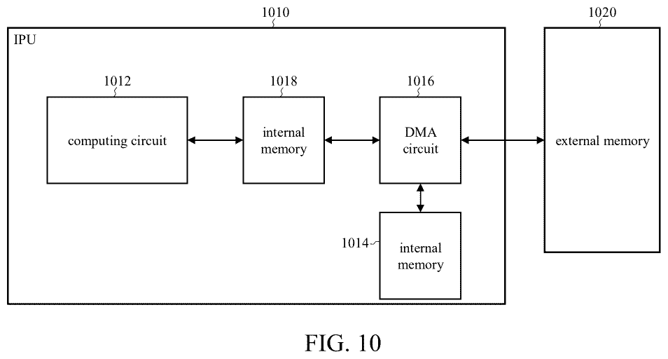

FIG. 10 is a functional block diagram of an electronic device according to an embodiment of the present invention. The electronic device 1000 is similar to the electronic device 200, with the IPU 1010, the computing circuit 1012, the internal memory 1014, the DMA circuit 1016, and the external memory 1020 corresponding to the IPU 210, the computing circuit 212, the internal memory 214, the DMA circuit 216, and the external memory 220 respectively. The IPU 1010 further includes an internal memory 1018. In other words, the IPU 1010 includes two internal memories. The DMA circuit 1016 updates the internal memory 1014 with the data from the external memory 1020 and updates the internal memory 1018 with the data from the internal memory 1014.

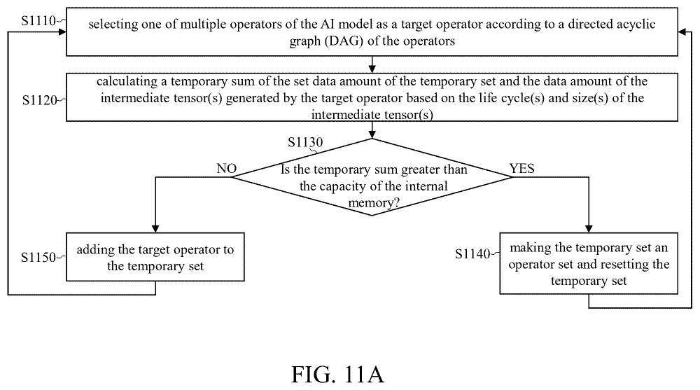

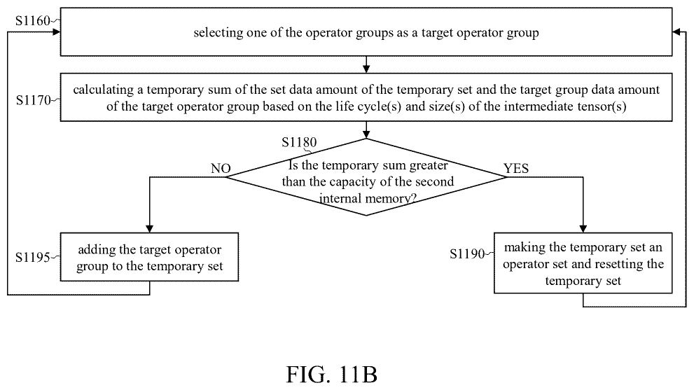

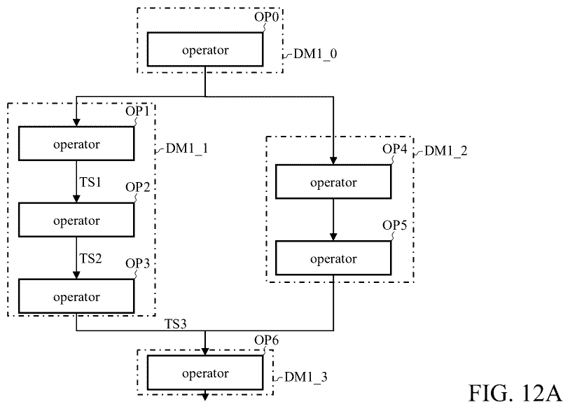

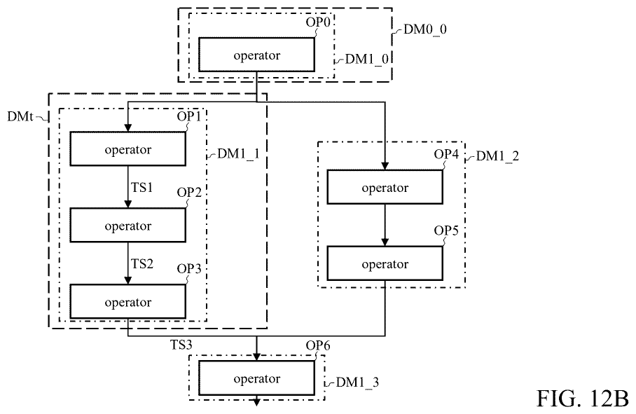

Based on the IPU 1010 having two internal memories, this disclosure proposes an alternative method for operator division. Reference is made to FIGS. 11A to 11B, which are the flowcharts of step S420 in FIG. 4 according to another embodiment of the present invention. The process of FIG. 11A divides multiple operators in an AI model into multiple operator groups based on the capacity of the internal memory 1018, while the process of FIG. 11B divides multiple operator groups into multiple operator sets based on the capacity of the internal memory 1014. FIG. 11A is similar to FIG. 6 (steps S1110 to S1150 correspond to steps S610 to S650 respectively), and the first internal memory of step S1130 is the internal memory 1018. Reference is made to FIG. 12A. In an example, after the process of FIG. 11A is finished, the operators OP0 to OP6 are divided into 4 operator groups: DM1_0 to DM1_3.

After finishing the process in FIG. 11A, the development device continues to execute the process in FIG. 11B which includes the following steps.

Step S1160: Selecting one of the operator groups as a target operator group. Reference is made to FIG. 12B. The following discussion is based on an example in which the temporary set DMt solely includes the operator group DM1_1, and the target operator group is the operator group DM1_2. Similar to step S910, step S1160 may select a target operator group based on the DFS algorithm to shorten the life cycle(s) of the intermediate tensor(s).

Step S1170: Calculating the temporary sum of the set data amount of the temporary set DMt (i.e., the peak of the intermediate tensor(s) in the temporary set DMt) and the target group data amount of the target operator group (i.e., the peak of the intermediate tensor(s) in the target operator group) based on the life cycle(s) and size(s) of the intermediate tensor(s). Continuing the previous example, the set data amount refers to the total data amount of the most concurrently alive intermediate tensors in the temporary set DMt, while the target group data amount refers to the total data amount of the most concurrently alive intermediate tensors in the operator group DM1_2.

Step S1180: Determining whether the temporary sum is greater than the capacity of the second internal memory (i.e., the internal memory 1014). This step is similar to step S630; hence, the details are omitted for brevity.

Step S1190 and step S1195 are similar to step S640 and step S650 respectively; hence, the details are omitted for brevity.

When the IPU 1010 executes the AI model, the computing circuit 1012 executes each operator set in the order of the operator sets. Within the operator set, the operator groups are executed in the order of the operator groups. Within the operator group, the operators are executed in the order of the operators. In this way, the IPU 1010 can effectively utilize the internal memory 1014 and the internal memory 1018.

In comparison with the embodiment of FIG. 2, the IPU 1010 of FIG. 10 has one more internal memory, so that the operators may be first divided into operator groups, and the operator groups are then divided into operator set(s). The advantage of introducing the operator groups is that when the tensors in the internal memory 1018 need to be rearranged (e.g., for dimension conversion), the DMA circuit 1016 only needs to move the data between the internal memory 1018 and the internal memory 1014 to complete the rearrangement of the tensors. In comparison, for the IPU 210 of FIG. 2, the rearrangement of the tensors requires writing and reading data to and from the external memory 220, which increases the bandwidth requirement of the IPU 210 for the external memory 220.

In some embodiments, the capacity of the internal memory 1014 is greater than the capacity of the internal memory 1018. Note that the bandwidth requirement for the external memory 1020 does not increase in cases where the data in the internal memory 1018 needs to be updated, because the DMA circuit 1016 obtains the data from the internal memory 1014, not from the external memory 1020.

Reference is made back to FIG. 4. After obtaining the relationship between the bandwidth requirement and the batch threshold N in FIG. 5 (i.e., after completing the method 400 for creating an AI model), the to-be-processed batch number in actual operations can be split based on the relationship, so that the execution of the AI model will be more efficient (e.g., reducing the bandwidth requirement). For example, the developer or manufacturer of the electronic device 200 (or the electronic device 1000) can split the to-be-processed batch number by calling one of the functions of the software development kit (SDK) provided by the developer or manufacturer of the IPU 210 (or the IPU 1010).

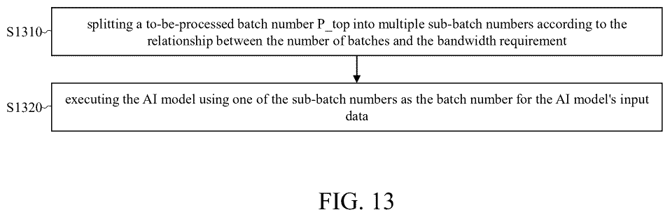

Reference is made to FIG. 13, which is a method for executing AI according to an embodiment of the present invention, which includes the following steps.

Step S1310: splitting the to-be-processed batch number P_top into multiple sub-batch numbers according to the relationship between the number of batches and the bandwidth requirement. The above function may correspond to step S1310.

Step S1320: Executing the AI model using one of the sub-batch numbers as the batch number for the AI model's input data. As previously discussed, the IPU can effectively utilize its internal memory when executing the AI model according to the sub-batch numbers of input data.

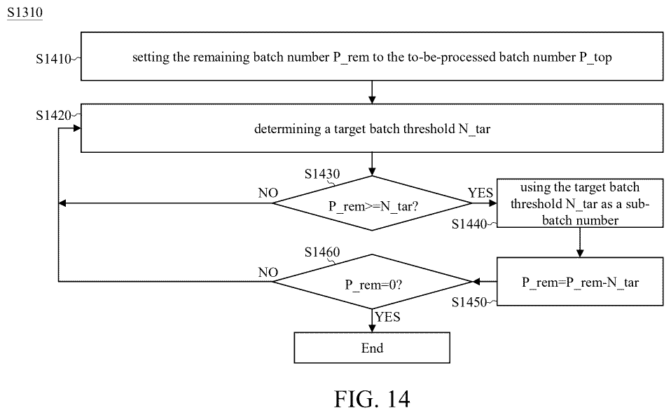

Reference is made to FIG. 14, which is the flowchart of step S1310 in FIG. 13 according to an embodiment of the present invention. Step S1310 includes the following sub-steps.

Step S1410: First, setting the remaining batch number P_rem to the to-be-processed batch number P_top.

Step S1420: Determining the target batch threshold N_tar. For example, in FIG. 5, since the batch threshold N contains 16, 8, 4, 2, 1, the above function determines the target batch threshold N_tar according to the default order (e.g., descending power), (e.g., the target batch threshold N_tar is equal to 16, 8, 4, 2, 1 in order).

Step S1430: Determining whether the remaining batch number P_rem is greater than or equal to the target batch threshold N_tar. If YES, the flow proceeds to step S1440; otherwise, the flow returns to step S1420 to select the next batch threshold N as the target batch threshold N_tar.

Step S1440: Using the target batch threshold N_tar as a sub-batch number.

Step S1450: Updating the remaining batch number P_rem by subtracting the target batch threshold N_tar from the remaining batch number P_rem.

Step S1460: Determining whether the remaining batch number P_rem is 0. If YES, step S1310 ends; otherwise, the flow returns to step S1420.

In some embodiments, the electronic device 200 (or the electronic device 1000) is an image processing device, and a batch of input data may correspond to a human face. If the electronic device 200 (or electronic device 1000) needs to process 37 batches of input data (i.e., the to-be-processed batch number P_top is 37), then the function can split 37 into 4 sub-batch numbers: 16, 16, 4, 1, based on the relationship in FIG. 5 (more specifically, based on the batch threshold N). That is to say, when the electronic device 200 (or the electronic device 1000) actually executes the AI model, the AI model substantially performs the operation of the same operator on N batches of input data (N being one of the batch thresholds) at the same time (refer to the discussion about FIG. 3).

Consequently, no matter what the actual application is, the IPU 210 (or IPU 1010) can reduce the bandwidth requirement for the external memory 220 (or external memory 1020).

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A method for creating an artificial intelligence (AI) model, wherein the method is applied to an intelligence processing unit (IPU) comprising a computing circuit and a memory, the AI model comprises a plurality of operators, and the computing circuit generates an intermediate tensor in a process of executing each operator, the method comprising:
(A) dividing the plurality of operators according to a batch threshold, life cycles of the intermediate tensors, sizes of the intermediate tensors, and a capacity of the memory;
(B) calculating a bandwidth requirement of the IPU for an external memory when executing the AI model; and
(C) storing a relationship between the batch threshold and the bandwidth requirement;
wherein the AI model performs an operation of a same operator on N batches of input data substantially simultaneously, N being a positive integer.

2. The method of claim 1, wherein step (A) comprises:
(A1) selecting one of the plurality of operators as a target operator according to a directed acyclic graph of the plurality of operators;
(A2) adding a data amount of the intermediate tensor generated by the target operator to a set data amount of a temporary set to obtain a temporary sum, wherein the temporary set includes at least one of the plurality of operators;
(A3) making the target operator as a part of the temporary set when the temporary sum is not greater than the capacity of the memory;
(A4) repeating steps (A1) to (A3) until the temporary sum is greater than the capacity of the memory; and
(A5) making the temporary set as an operator set.

3. The method of claim 2, wherein step (A1) selects the target operator based on a depth-first search (DFS) algorithm.

4. The method of claim 1, wherein the memory is a first memory, the capacity is a first capacity, and the IPU further comprises a second memory, step (A) comprising:
(A1) selecting one of the plurality of operators as a target operator according to a directed acyclic graph of the plurality of operators;
(A2) adding a data amount of the intermediate tensor generated by the target operator to a group data amount of a temporary group to obtain a first temporary sum, wherein the temporary group includes at least one of the plurality of operators;
(A3) making the target operator as a part of the temporary group when the first temporary sum is not greater than the first capacity of the first memory;
(A4) repeating steps (A1) to (A3) until the first temporary sum is greater than the first capacity of the first memory;
(A5) making the temporary group as an operator group;
(A6) repeating steps (A1) to (A5) to obtain a plurality of operator groups;
(A7) selecting one of the plurality of operator groups as a target operator group;
(A8) adding a target group data amount of the target operator group to a set data amount of a temporary set to obtain a second temporary sum, wherein the temporary set includes at least one of the plurality of operator groups;
(A9) making the target operator group as a part of the temporary set when the second temporary sum is not greater than a second capacity of the second memory;
(A10) repeating steps (A7) to (A9) until the second temporary sum is greater than the second capacity of the second memory; and
(A11) making the temporary set as an operator set.

5. The method of claim 4, wherein step (A1) selects the target operator based on a depth-first search (DFS) algorithm.

6. The method of claim 5, wherein step (A7) selects the target operator group based on the DFS algorithm.

7. The method of claim 1 further comprising:
(D) adjusting the batch threshold and repeating steps (A) to (C) to obtain a plurality of batch thresholds until a trend of the bandwidth requirement changes;
wherein N is one of the plurality of batch thresholds.

8. The method of claim 1 further comprising:
(D) increasing the batch threshold and repeating steps (A) to (C) to obtain a plurality of batch thresholds until the bandwidth requirement increases;
wherein N is one of the plurality of batch thresholds.

9. A method for executing an artificial intelligence (AI) model, wherein the method is applied to an electronic device comprising an intelligence processing unit (IPU) and a memory, the IPU does not comprise the memory, the AI model performs an operation of a same operator on M batches of input data substantially simultaneously, and M is a positive integer, the method comprising:
(A) splitting a to-be-processed batch number into a plurality of sub-batch numbers according to a plurality of batch thresholds and a plurality of bandwidth requirements of the IPU for the memory, wherein the plurality of batch thresholds and the plurality of bandwidth requirements correspond to each other; and
(B) executing the AI model using one of the plurality of sub-batch numbers as the M.

10. The method of claim 9, wherein step (A) comprises:
(A1) setting a remaining batch number to the to-be-processed batch number;
(A2) determining a target batch threshold;
(A3) using the target batch threshold as a sub-batch number, and setting the remaining batch number to the remaining batch number minus the target batch threshold when the remaining batch number is greater than or equal to the target batch threshold; and
(A4) repeating steps (A2) to (A3) until the remaining batch number is zero.
